(19) United States
(12) Patent Application Publication
(10) Pub. No.: US 2011/0175050 A1
(43) Pub. Date: Jul. 21, 2011

(54) Metal Oxide Resistance Based Semiconductor Memory Device With High Work Function Electrode

(75) Inventors: Wei-Chih Chien, Sijhih City (TW); Yi-Chou Chen, Hsinchu City (TW)

(73) Assignee: Macronix International Co., Ltd., Hsinchu (TW)

(21) Appl. No.: 12/878,861

(22) Filed: Sep. 9, 2010

Related U.S. Application Data
(60) Provisional application No. 61/296,231, filed on Jan. 19, 2010.

(51) Int. Cl. H01L 45/00; H01L 21/16

(52) U.S. Cl. 257/4; 438/104; 257/E45.003; 257/E21.078

(57) ABSTRACT

Various aspect are directed to a memory device or memory cell with a metal-oxide memory element arranged in electrical series along a current path between at least a first electrode, a metal-oxide memory element adjacent to the first electrode, and a second electrode. The first electrode comprises an electrode material having a first work function. The metal-oxide memory element comprises a metal-oxide material having a second work function. The first work function is greater than the second work function. Thermionic emission characterizes the current through this memory.

### RELATED APPLICATIONS

This application claims the benefit under 35 U.S.C. §119(e) of U.S. Provisional Application No. 61/296,231, filed on 19 Jan. 2010, which is incorporated herein by reference.

### BACKGROUND

The present invention relates to metal-oxide based memory devices, methods for manufacturing such devices, and methods for operating such devices.

### SUMMARY

Various embodiments are directed to one or more of: reducing the forming current, reducing the switching current, enhancing the resistance window, and enhancing the retention property. Some embodiments are called resistance RAM or ReRAM or RRAM.

One aspect is a memory device comprising a metal-oxide memory element.

The metal-oxide memory element is arranged in electrical series along a current path between at least a first electrode, a metal-oxide memory element adjacent to the first electrode, and a second electrode. The first electrode comprises an electrode material having a first work function. The metal-oxide memory element comprises a metal-oxide material having a second work function. The first work function is greater than the second work function.

In one embodiment, the first electrode is a top electrode and the second electrode is a bottom electrode.

In one embodiment, current through the current path is characterized by thermionic emission.

In one embodiment, the electrode material includes at least one of the following metals: Yb, Tb, Y, La, Sc, Hf, Zr, Al, Ta, Ti, Nb, Cr, V, Zn, W, Mo, Cu, Re, Ru, Co, Ni, Rh, Pd, Pt.

In one embodiment, the current path further includes, between the metal-oxide memory element and the second electrode, at least a metal element.

In one embodiment, the memory device has a resistance window of at least about a factor of 100.

In one embodiment, the electrode material comprises a metal having a first free energy of formation of an oxide that is similar to a second free energy of formation of the metal-oxide material in the metal-oxide memory element.

In one embodiment, the electrode material comprises a metal having a first free energy of formation of an oxide that is within about 0.1 eV of a second free energy of formation of the metal-oxide material in the metal-oxide memory element.

In one embodiment, the memory device has a reset current of no more than about 300 microamperes and a set current of no more than about 200 microamperes.

In one embodiment, the memory device has a reset current density of no more than about 1.2 mega-amperes per square centimeter and a set current density of no more than about 0.75 mega-amperes per square centimeter.

Another aspect is a memory device comprising a plurality of word lines, a plurality of bit lines, and a plurality of memory cells accessed by the plurality of word lines and plurality of bit lines.

Memory cells in the plurality of memory cells include a metal-oxide memory element arranged in electrical series along a current path between at least a word line of the plurality of word lines and a bit line of the plurality of bit lines. The metal-oxide memory element is adjacent to a first electrode comprising an electrode material having a first work function. The metal-oxide memory element comprises a metal-oxide material having a second work function. The first work function is greater than the second work function.

In one embodiment, the first electrode is a top electrode and the second electrode is a bottom electrode.

In one embodiment, current through the current path is characterized by thermionic emission.

In one embodiment, the electrode material includes at least one of the following metals: Yb, Tb, Y, La, Sc, Hf, Zr, Al, Ta, Ti, Nb, Cr, V, Zn, W, Mo, Cu, Re, Ru, Co, Ni, Rh, Pd, Pt.

In one embodiment, the current path further includes, between the metal-oxide memory element and the second electrode, at least a metal element.

In one embodiment, memory cells in the plurality of memory cells have a resistance window of at least about a factor of 100.

In one embodiment, the electrode material comprises a metal having a first free energy of formation of an oxide that is similar to a second free energy of formation of the metal-oxide material in the metal-oxide memory element.

In one embodiment, the electrode material comprises a metal having a first free energy of formation of an oxide that is within about 0.1 eV of a second free energy of formation of the metal-oxide material in the metal-oxide memory element.

In one embodiment, memory cells in the plurality of memory cells have a reset current of no more than about 300 microamperes and a set current of no more than about 200 microamperes.

In one embodiment, memory cells in the plurality of memory cells have a reset current density of no more than about 1.2 mega-amperes per square centimeter and a set current density of no more than about 0.75 mega-amperes per square centimeter.

Yet another aspect is a manufacturing method, comprising:
providing a metal-oxide memory element arranged in electrical series along a current path between at least a first electrode, a metal-oxide memory element adjacent to the first electrode, and a second electrode, wherein the first electrode comprises an electrode material having a first work function, the metal-oxide memory element comprises a metal-oxide material having a second work function, and the first work function is greater than the second work function.

Various embodiments are disclosed herein.

### BRIEF DESCRIPTION OF THE DRAWINGS

FIG. 1 illustrates a schematic diagram of a portion of a cross-point memory array implemented using memory cells as described herein.

FIGS. 2A and 2B illustrate cross-sectional views of a portion of an embodiment of memory cells arranged in the cross point array.

FIGS. 3-6 illustrate steps in a fabrication sequence for manufacturing the cross-point array of memory cells as illustrated in FIGS. 2A-2B.

FIG. 7 is a simplified block diagram of an integrated circuit including a cross-point array of memory cells having a metal-oxide based memory element and a diode access device as described herein.

FIG. 8 shows the structure and the device fabrication process flow of an exemplary ReRAM cell.

FIG. 9 shows IV curves for the initial, RESET and SET states of an ReRAM cell with a TiN top electrode, following the SCLC (space charge limit current) current mechanism.

FIG. 10 shows equations for the SCLC current mechanism.

FIG. 11 shows IV curves for the RESET and SET states of an ReRAM cell with a TiN top electrode at 25° C., 50° C., 75° C., and 100° C., following the SCLC (space charge limit current) mechanism.

FIG. 12 shows graphs of SCLC mechanism equation components to find the activation energy Ea for the RESET and SET states of an ReRAM cell with a TiN top electrode.

FIG. 13 shows the resistance windows of ReRAM cells with different top electrode materials.

FIG. 14 shows a graph of the initial resistance versus the work function of the top electrode the ReRAM cell.

FIG. 15 shows equations for the thermionic emission current mechanism.

FIG. 16 shows the initial state IV curves for ReRAM cells with Pt, Ni, and TiN top electrodes, showing thermionic emission with the Pt and Ni top electrodes and SCLC with the TiN top electrode.

FIG. 17 shows graphs of thermionic emission current mechanism equation components for Pt/WO_{X}/W and Ni/WO_{X}/W ReRAM cells at a number of different voltage biases, indicating thermionic emission.

FIG. 18 shows bandgap diagrams of the top electrode and WOx metal-oxide memory element for WO_{X} ReRAM with Pt, Ni, and TiN top electrodes.

FIG. 19 shows the cross-sectional TEM of the Ni(200 nm)/WO_{X}(70 nm)/W ReRAM cell.

FIG. 20 shows the I-t curve of the anti-forming process, and transient I-t curves for RESET and SET processes, for the Ni/WO_{X}/W ReRAM cell.

FIG. 21 shows resistance vs. cycle characteristics for RESET and SET states of the Ni/WO_{X}/W ReRAM cell.

FIG. 22 shows resistance versus stress time for read disturb testing for RESET and SET states of the Ni/WO_{X}/W ReRAM cell.

FIG. 23 shows resistance versus baking time for thermal stability testing for RESET and SET states of the Ni/WO_{X}/W ReRAM cell.

FIG. 24 shows further retention testing of the Ni/WO_{X}/W ReRAM cell.

FIG. 25 shows a table of different characteristics comparing TiN/WO_{X}/W, Pt/WO_{X}/W, and Ni/WO_{X}/W ReRAM cells.

FIG. 26 is a graph of free energy of formation of a metal oxide versus work function for the metal of the metal oxide, for different metals.

### DETAILED DESCRIPTION

The following description of the disclosure will typically be with reference to specific structural embodiments and methods. It is to be understood that there is no intention to limit the disclosure to the specifically disclosed embodiments and methods, but that the disclosure may be practiced using other features, elements, methods and embodiments. Preferred embodiments are described to illustrate the present disclosure, not to limit its scope, which is defined by the claims. Those of ordinary skill in the art will recognize a variety of equivalent variations on the description that follows. Like elements in various embodiments are commonly referred to with like reference numerals.

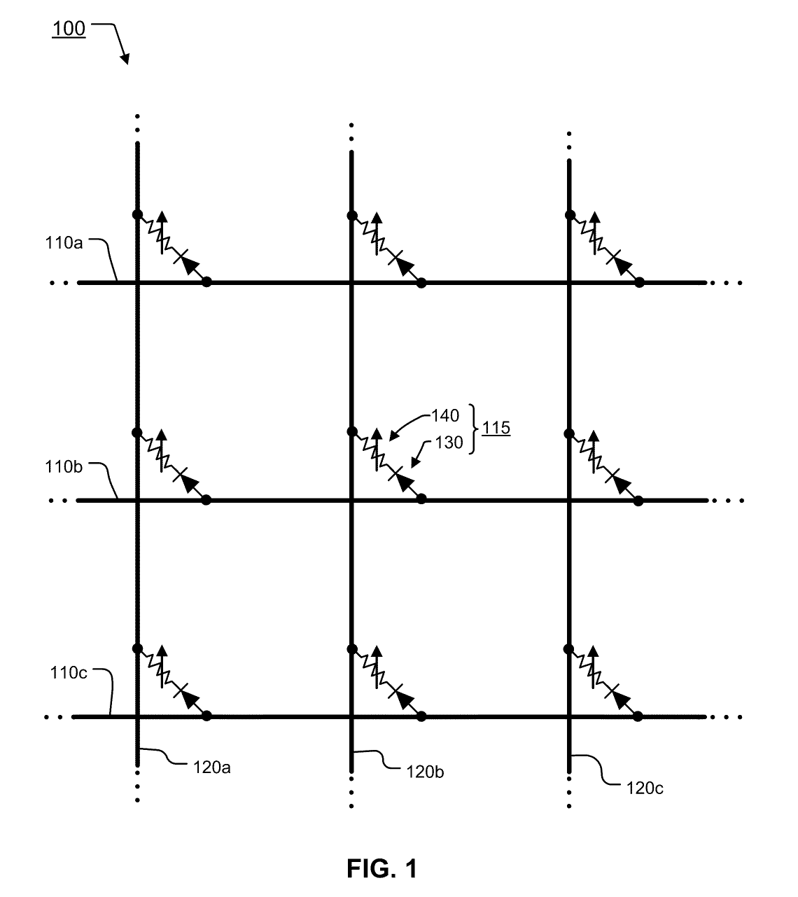

FIG. 1 illustrates a schematic diagram of a portion of a cross-point memory array 100 implemented using memory cells as described herein, each memory cell comprising a diode access device and a metal-oxide based memory element.

As shown in the schematic diagram of FIG. 1, each of the memory cells of the array 100 include a diode access device and a metal-oxide based memory element (each represented in FIG. 1 by a variable resistor) arranged in series along a current path between a corresponding word line 110 and a corresponding bit line 120. As described in more detail below, the memory element in a given memory cell is programmable to plurality of resistance states including a first and a second resistance state.

The array comprises a plurality of word lines 110 including word lines 110a, 110b, and 110c extending in parallel in a first direction, and a plurality of bit lines 120 including bit lines 120a, 120b, and 120c extending in parallel in a second direction perpendicular to the first direction. The array 100 is referred to as a cross-point array because the word lines 110 and bit lines 120 cross each other but do not physically intersect, and the memory cells are located at these cross-point locations of the word lines 110 and bit lines 120.

Memory cell 115 is representative of the memory cells of array 100 and is arranged at the cross-point location of the word line 110b and the bit line 120b, the memory cell 115 comprising a diode 130 and a memory element 140 arranged in series. The diode 140 is electrically coupled to the word line 110b and the memory element 140 is electrically coupled to the bit line 120b.

Reading or writing to memory cell 115 of array 100 can be achieved by applying appropriate voltage pulses to the corresponding word line 110b and bit line 120b to induce a current through the selected memory cell 115. The level and duration of the voltages applied is dependent upon the operation performed, e.g. a reading operation or a programming operation.

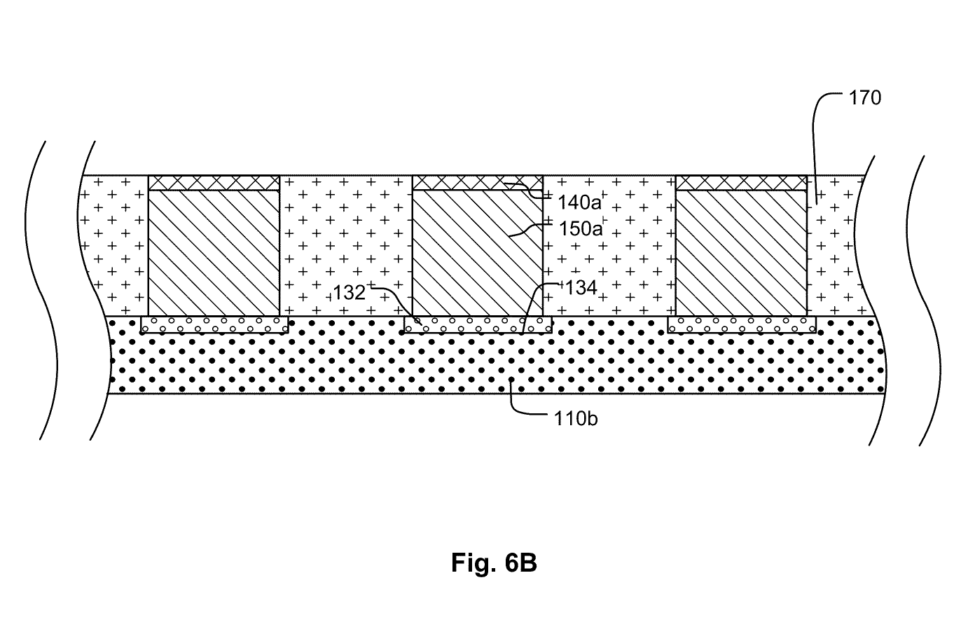

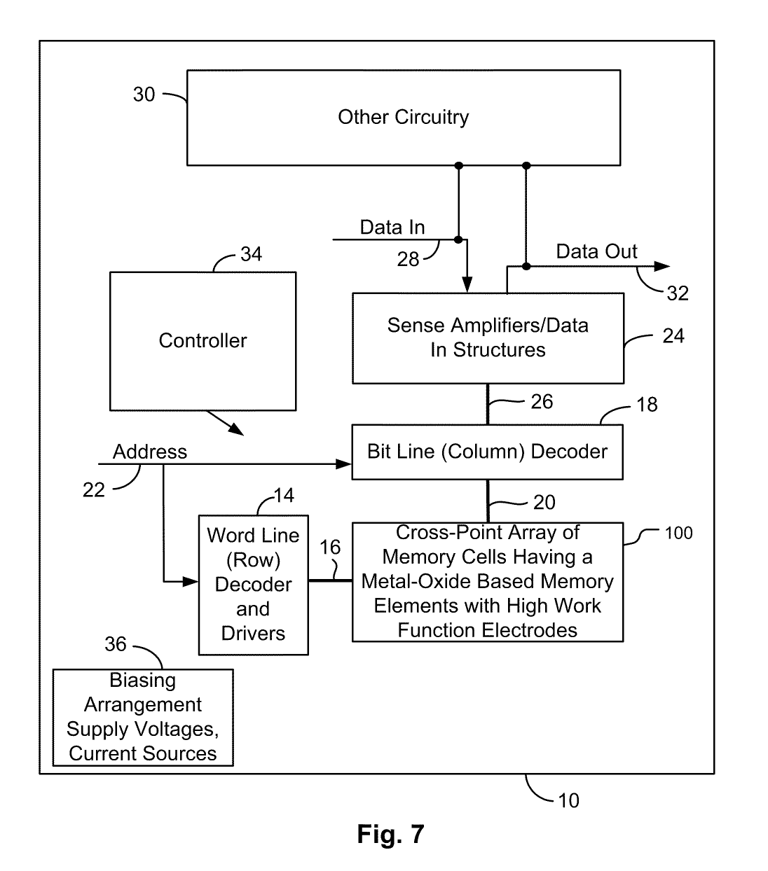

In a read (or sense) operation of the data value stored in the memory cell 115, bias circuitry (See, for example, biasing arrangement supply voltages, current sources 36 of FIG. 7) coupled to the corresponding word line 110b and bit line 120b to apply bias arrangements across the memory cell 115 of suitable amplitude and duration to induce current to flow which does not result in the memory element 140 undergoing a change in resistive state. The current through the memory cell 115 is dependent upon the resistance of the memory element 140 and thus the data value stored in the memory cell 115. The data value may be determined, for example, by comparison of the current on the bit line 120b with a suitable reference current by sense amplifiers (See, for example, sense amplifiers/data in structures 24 of FIG. 7).

In a program operation of a data value to be stored in the memory cell 115, bias circuitry (See, for example, biasing arrangement supply voltages, current sources 36 of FIG. 7) coupled to the corresponding word line 110b and bit line 120b to apply bias arrangements across the memory cell 115 of suitable amplitude and duration to induce a programmable change in the memory elements 140 to store the data value in the memory cell 115, the electrical resistance of the memory element 140 corresponding to the data value stored in the memory cell 115.

The bias arrangements include a first bias arrangement sufficient to forward bias the diode 130 and change the resistance state of the memory element 140 from a resistance corresponding to a first programmed state to a resistance corresponding to a second programmed state. The bias arrangements also include a second bias arrangement sufficient to forward bias the diode 130 and change the resistance state of the memory element 140 from a resistance corresponding to the second programmed state to a resistance corresponding to the first programmed state. In embodiments the bias arrangements for unipolar operation of the memory element 140 may each comprise one or more voltage pulses, and the voltage levels and pulse times can be determined empirically for each embodiment.

In some embodiments, the separate diode element is necessary as an access device, because the barrier formed by the interface between a high work function contact and the metal-oxide memory element acts as a diode or Schottky junction access device with an insufficiently high barrier to prevent leakage current.

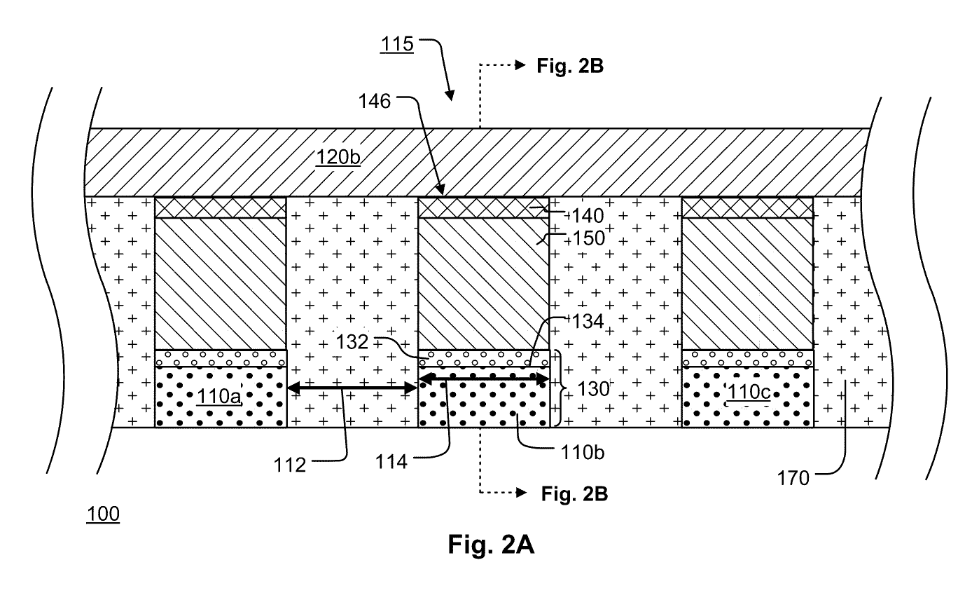

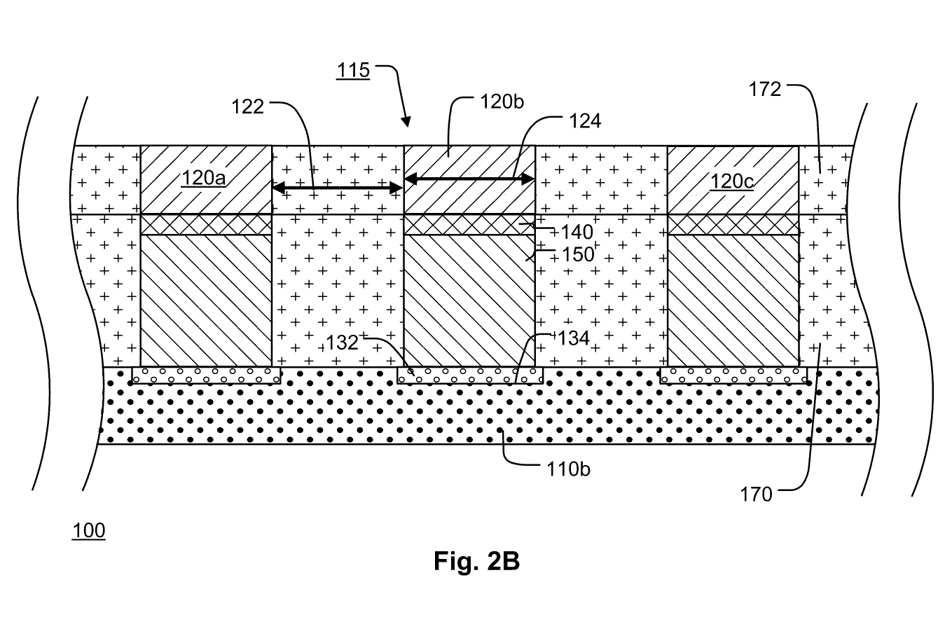

FIGS. 2A and 2B illustrate cross-sectional views of a portion of an embodiment of memory cells (including representative memory cell 115) arranged in the cross-point array 100, FIG. 2A taken along the bit lines 120 and FIG. 2B taken along the word lines 110.

Referring to FIGS. 2A and 2B, the memory cell 115 includes a doped semiconductor region 132 within the word line 110b. The word lines 110 comprise doped semiconductor material having a conductivity type opposite that of the doped semiconductor region 132. Thus, the doped semiconductor region 132 and the word line 110b define a pn junction 134 therebetween, and the diode 130 comprises the doped semiconductor region 132 and a portion of the word line 110b adjacent the doped semiconductor region 132. In the illustrated embodiment the word lines 110 comprise doped P-type semiconductor material such as polysilicon, and the doped semiconductor region 132 comprises doped N-type semiconductor material.

In an alternative embodiment the word lines 130 may comprise other conductive materials such as W, TiN, TaN, Al and the diode may be formed by first and second doped regions having different conductivity types on the word lines 110. In yet another alternative embodiment, the diode may be formed by a lightly doped region between more highly doped regions of opposite conductivity since it has been observed that the breakdown voltage of the diode can be improved. In yet another alternative embodiment, the word lines may comprise a high work function metal material as discussed below.

The memory cell 115 includes a conductive element 150 extending through dielectric 170 to couple the diode 130 to memory element 140.

In the illustrated embodiment the conductive element 150 comprises tungsten and the memory element 140 comprise tungsten-oxide WO_{X}.

Embodiments for forming the memory element 140 in the illustrated embodiment comprising tungsten-oxide include direct plasma oxidation, down-stream plasma oxidation, thermal diffusion oxidation, sputtering, and reactive sputtering. Embodiments of the plasma oxidation process include a pure O₂ gas chemistry, or mix chemistries such as O₂/N₂, or O₂/N₂/H₂. In one embodiment of the down-stream plasma, the down-stream plasma is applied with a pressure of about 1500 mtorr, a power of about 1000 W, the rate of O₂/N₂ flow ranging from 0.1 to 100, a temperature of about 150° C., and a time duration ranging from 10 to 2000 seconds. See, for example, U.S. patent application Ser. No. 11/955,137, or US Patent Application Publication No. 2008/0304312, which is incorporated by reference herein.

In alternative embodiments the memory element 140 may comprise one or more metal oxides from the group of titanium oxide, nickel oxide, aluminum oxide, copper oxide, zirconium oxide, titanium nickel oxide, strontium zirconium oxide, and praseodymium calcium manganese oxide.

The bit lines 120, including bit line 120b acting as a top electrode for the memory cell 115, are electrically coupled to the memory elements 140 and extend into and out of the cross-section illustrated in FIG. 2B. The bit lines 120 comprise one or more layers of conductive material. The bit lines 120 may comprise Ni or Pt or other high work function conducting materials.

Dielectric 174 separates adjacent bit lines 120. In the illustrated embodiment the dielectrics 170, 172 comprise silicon oxide. Alternatively, other dielectric materials may be used.

As can be seen in the cross-sections illustrated in FIGS. 2A and 2B, the memory cells of the array 100 are arranged at the cross-point locations of the word lines 110 and bit lines 120. Memory cell 115 is representative and is arranged at the cross-point location of word line 110b and bit line 120b. Additionally, the memory elements 140 and conductive elements 150, 160 have a first width substantially the same as the width 114 of the word lines 110 (See FIG. 2A). Furthermore, the memory elements 140 and conductive elements 150, 160 have a second width substantially the same as the width 124 of the bit lines 120 (See FIG. 2B). As used herein, the term “substantially” is intended to accommodate manufacturing tolerances. Therefore, the cross-sectional area of the memory cells of array 100 is determined entirely by dimensions of the word lines 110 and bit lines 120, allowing for a high memory density for array 100.

The word lines 110 have word line widths 114 and are separated from adjacent word lines 110 by a word line separation distance 112 (See FIG. 2A), and the bit lines 120 have bit line widths 124 and are separated from adjacent bit lines 120 by a bit line separation distance 122 (See FIG. 2B). In preferred embodiments the sum of the word line width 114 and the word line separation distance 112 is equal to twice a feature size F of a process used to form the array 100, and the sum of the bit line width 124 and the bit line separation distance 122 is equal to twice the feature size F. Additionally, F is preferably a minimum feature size for a process (typically a lithographic process) used to form the bit lines 120 and word lines 110, such that the memory cells of array 100 have a memory cell area of 4 F².

In the memory array 100 illustrated in FIGS. 2A-2B, the memory element 140 is self-aligned with the conductive plug 150. In the manufacturing embodiment described in more detail below, the memory element 140 is formed by oxidation of the material of the conductive element 150.

In operation, bias circuitry (See, for example, biasing arrangement supply voltages, current sources 36 of FIG. 7) coupled to the corresponding word line 110b and bit line 120b applies bias arrangements across the memory cell 115 to forward bias the diode 130 and induce a programmable change in the resistance state of the memory element 140, the electrical resistance of the memory element 140 indicating the data value stored in the memory cell 115.

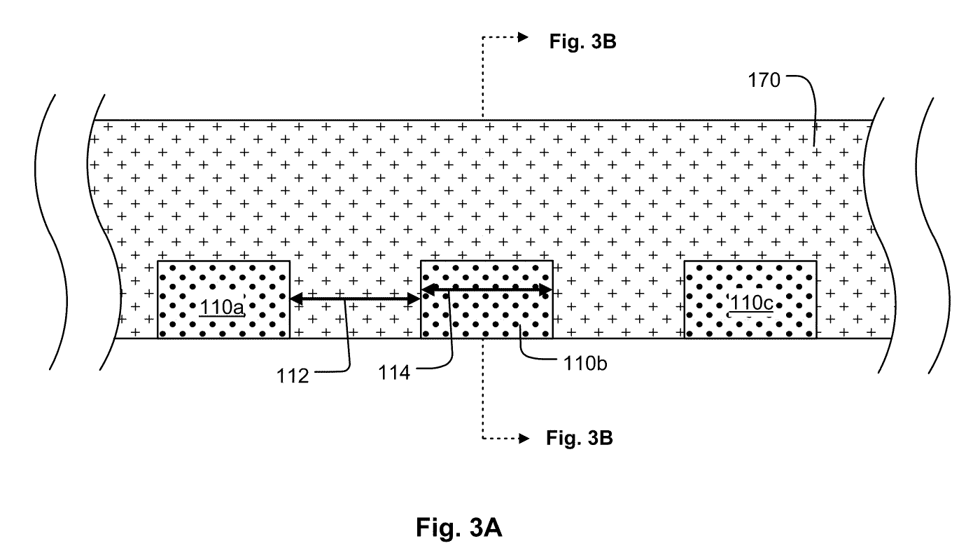

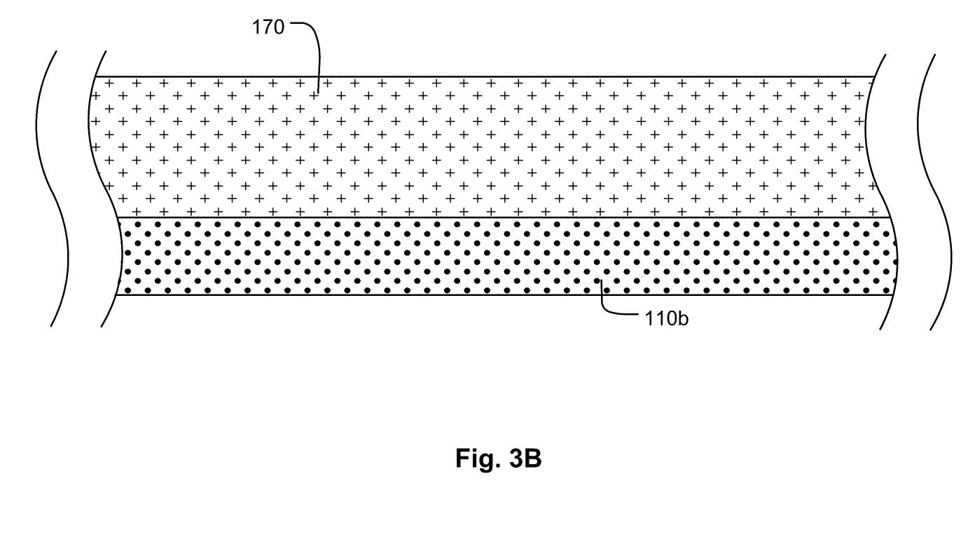

FIGS. 3-6 illustrate steps in a fabrication sequence for manufacturing the cross-point array 100 of memory cells as illustrated in FIGS. 2A-2B.

FIGS. 3A-3B illustrate cross-sectional views of a first step of forming word lines 110 on a substrate and dielectric 170 on the word lines 110. The word lines 110 extend in a first direction into and out of the cross-section illustrated in FIG. 3A, and in the illustrated embodiment comprise doped semiconductor material. The word lines 110 have word line width 114 and adjacent word lines are separated by word line separation distance 112.

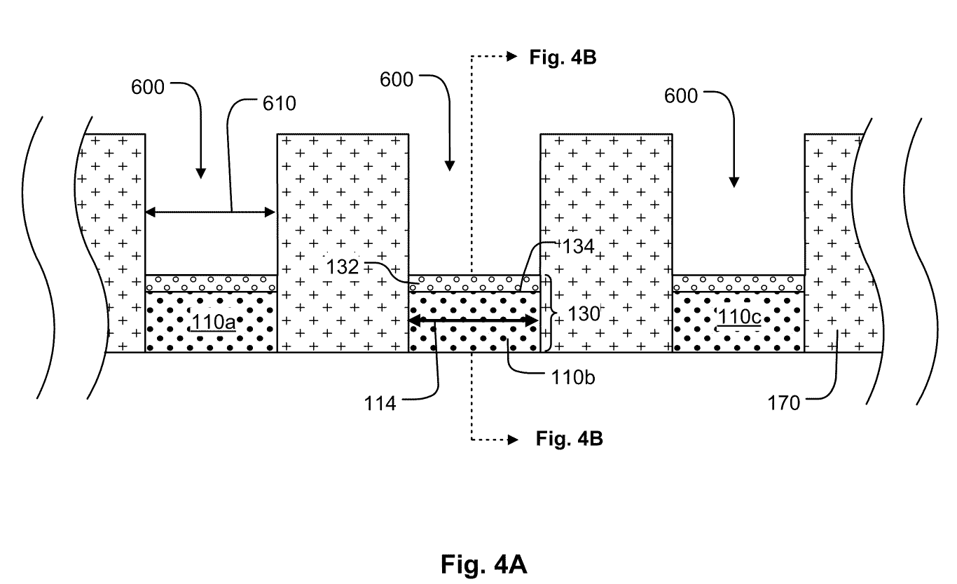

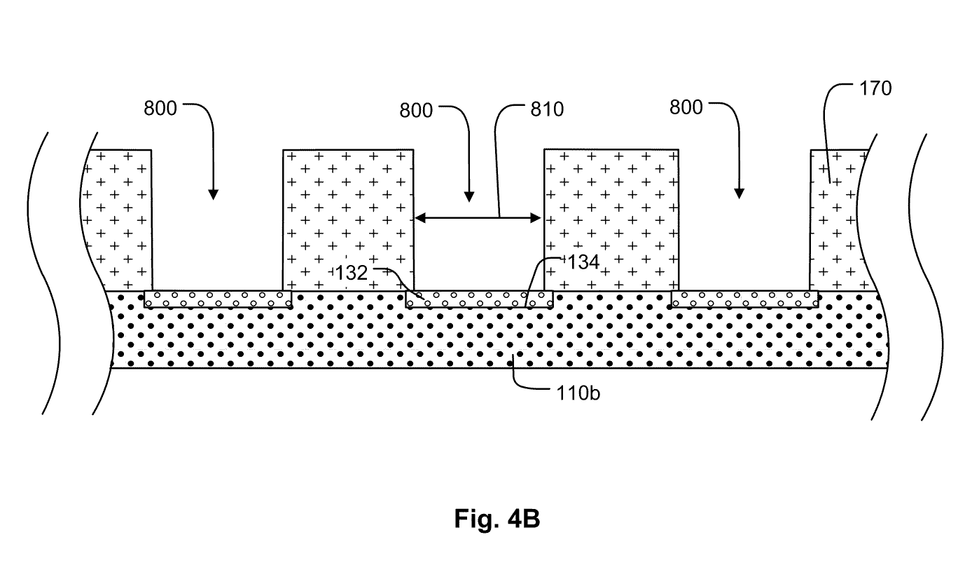

Next, an array of vias 600 having width 610 are formed in the dielectric 170 to expose portions of the word lines 110, and the doped semiconductor regions 132 are formed within the word lines 110, for example by ion implantation, resulting in the structure illustrated in the cross-sectional views of FIGS. 4A-4B. The doped semiconductor regions 132 have a conductivity type opposite that of the word lines 110. Thus the doped semiconductor regions 132 and word lines 110 define pn junctions 134, and the diode 130 comprises the doped semiconductor regions 132 and a portion of the word line 110 adjacent the doped semiconductor regions 132.

In some embodiments, the separate diode element is necessary as an access device, because the barrier formed by the interface between a high work function contact and the metal-oxide memory element acts as a diode or Schottky junction access device (with the high work function contact end being positioned at or closer to the word line end in one embodiment, and at or closer to the bit line end in another embodiment) is insufficiently high to prevent leakage current.

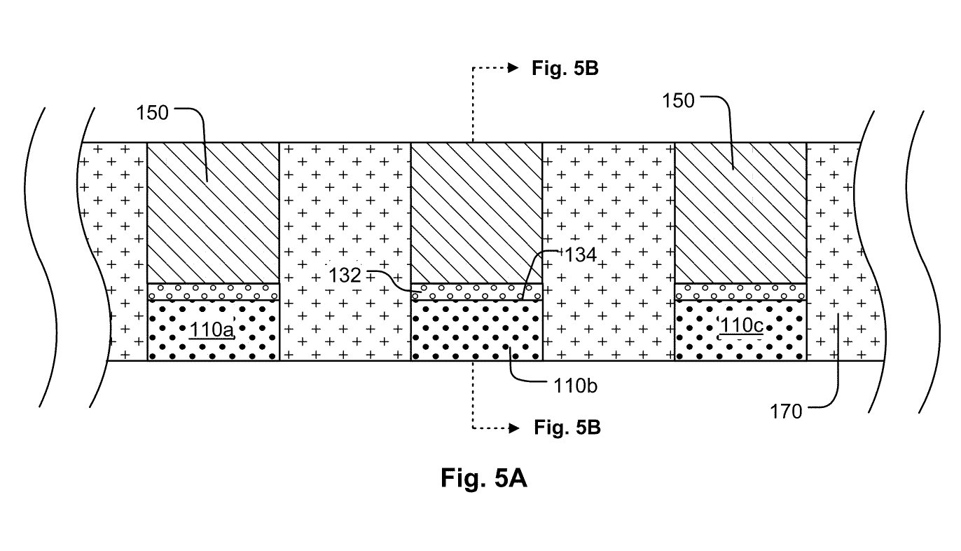

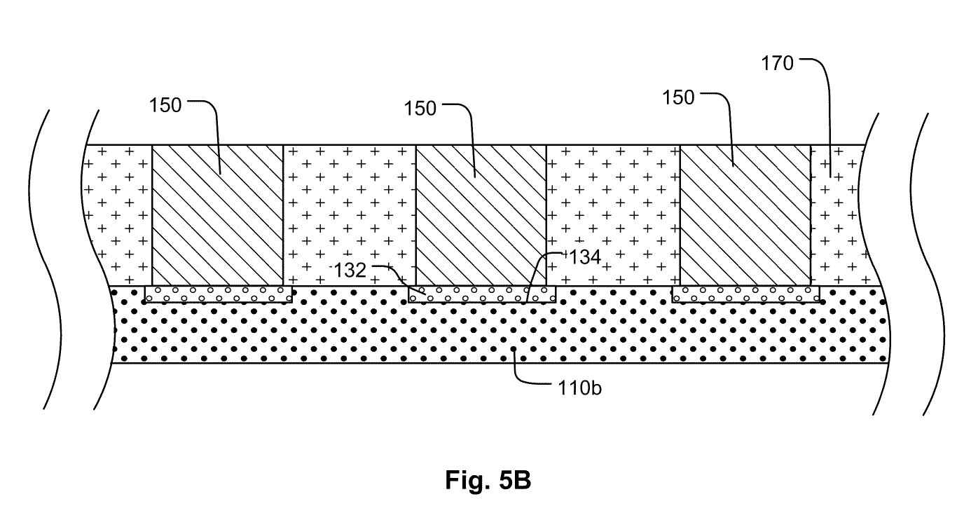

Next, conductive elements 150 are formed within the vias 600 of FIGS. 4A-4B, resulting in the structure illustrated in the cross-sectional views of FIGS. 5A-5B. The conductive elements 150 in the illustrated embodiment comprise tungsten material and can be formed within the vias 600 by Chemical Vapor Deposition CVD of tungsten material, followed by a planarization step such as Chemical Mechanical Polishing CMP.

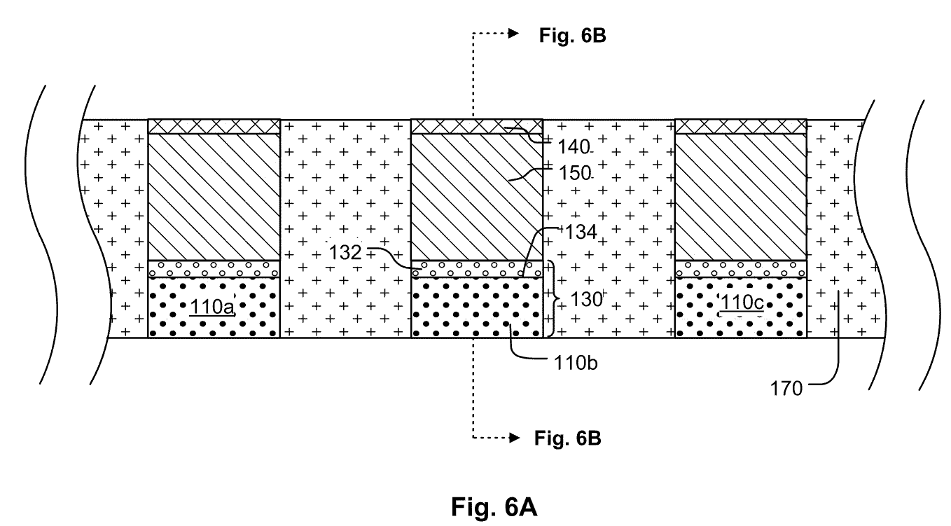

Next, oxidation of a portion of the conductive elements 150 forms memory elements 140 self-aligned with the remaining portion of the corresponding conductive elements 150, resulting in the structure illustrated in the cross-sectional views of FIGS. 6A and 6B. The oxidation can comprise plasma oxidation and an optional thermal oxidation step. For example, direct oxygen plasma oxidation or downstream oxygen plasma oxidation may be used. Embodiments include pure O₂ gas chemistry, or mixed chemistries such as O₂/N₂ or O₂/N₂/H₂. Since the memory elements 140 are formed by oxidation of the conductive elements 150, no additional masks are necessary to form the memory elements 140.

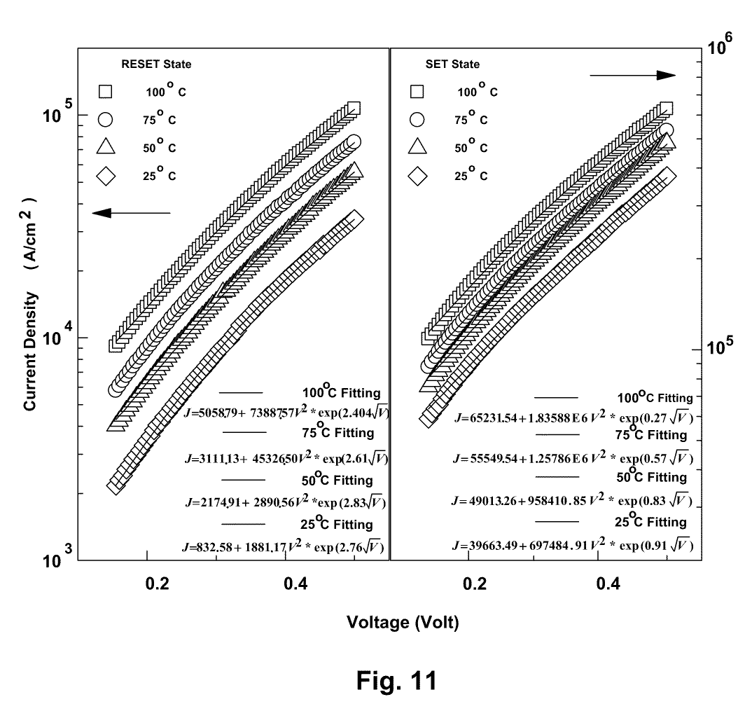

Next, the metal-oxide memory element 140 is optionally cured by exposing the metal-oxide memory element 140 to a gas comprising at least one of nitrogen, hydrogen, and argon, at a temperature greater than 100 degrees Celsius. More preferably the metal-oxide memory element 140 is exposed to the gas at a temperature greater than 150 degrees Celsius. Exposing the metal-oxide memory element 140 to the gas can be carried out using any suitable high temperature system including, for example, a furnace system or a rapid thermal pulse (“RTP” system). The time, temperature, and the pressure of the exposure process will depend on a number of factors, including the system used, and will vary from embodiment to embodiment. For example, the temperature can range from 150 degrees C. to 500 degrees C. with a time of 10 to 10,000 seconds, at a pressure of between 10⁻⁵ and 10⁻² torr. As discussed in more detail below with respect to FIGS. 11A-11B, curing the metal-oxide memory element as described herein is shown to improve the resistive switching performance and the cycle endurance of the metal-oxide memory element 140.

Next, high work function bit lines 130 formed using for example physical vapor deposition processes, separated by dielectric 174, are formed on the structure illustrated in FIGS. 6A-6B, resulting in the cross-point array 100 illustrated in FIGS. 2A-2B. In some embodiments, the optional exposure process of the memory element 140 as discussed above with respect to FIGS. 4A-4B is instead performed on the bit lines 130. Bias circuitry such as supply voltages and/or current sources can be formed on the same device as the memory elements and coupled to the word lines 110 and bit lines 120 for applying bias arrangements as described herein. The bit lines 130 and dielectric 174 may be formed by patterning a bit line material on the structure in FIGS. 4A-4B, forming dielectric on the bit lines 130, and performing a planarizing process such as Chemical Mechanical Polishing CMP.

FIG. 7 is a simplified block diagram of an integrated circuit 10 including a cross-point memory array 100 of memory cells having a metal-oxide based memory element and a diode access device as described herein. A word line decoder 14 is coupled to and in electrical communication with a plurality of word lines 16. A bit line (column) decoder 18 is in electrical communication with a plurality of bit lines 20 to read data from, and write data to, the memory cells (not shown) in array 100. Addresses are supplied on bus 22 to word line decoder and drivers 14 and bit line decoder 18. Sense amplifiers and data-in structures in block 24 are coupled to bit line decoder 18 via data bus 26. Data is supplied via a data-in line 28 from input/output ports on integrated circuit 10, or from other data sources internal or external to integrated circuit 10, to data-in structures in block 24. Other circuitry 30 may be included on integrated circuit 10, such as a general purpose processor or special purpose application circuitry, or a combination of modules providing system-on-a-chip functionality supported by array 100. Data is supplied via a data-out line 32 from the sense amplifiers in block 24 to input/output ports on integrated circuit 10, or to other data destinations internal or external to integrated circuit 10.

A controller 34 implemented in this example, using a bias arrangement state machine, controls the application of bias arrangement supply voltages 36, such as read, program, and program verify voltages. Controller 34 may be implemented using special-purpose logic circuitry as known in the art. In alternative embodiments, controller 34 comprises a general-purpose processor, which may be implemented on the same integrated circuit to execute a computer program to control the operations of the device. In yet other embodiments, a combination of special-purpose logic circuitry and a general-purpose processor may be utilized for implementation of controller 34.

As described above with respect to FIGS. 6A-6B, during manufacturing of memory cells with diode access devices, the metal-oxide memory element 140 can be cured by exposing the metal-oxide memory element to a gas comprising at least one of nitrogen, hydrogen, and argon.

Other metal-oxides such as titanium oxide, nickel oxide, aluminum oxide, copper oxide, zirconium oxide, niobium oxide, tantalum oxide, titanium-nickel oxide, Cr doped SrZrO₃, Cr doped SrTiO₃, PCMO, and LaCaMnO can be utilized with high work function top electrode materials.

This device can be used in bipolar operation and unipolar operation. Bipolar operation means the device can be operated by opposite polarity electrical field to SET or RESET. Unipolar operation means the device can be operated by same polarity electrical field to SET or RESET.

In addition to metal-oxide ReRAM, another application for various embodiments is spin torque transfer MRAM.

The work function (WF) of the electrode is a key element determining the conduction mechanism for WO_{X} ReRAM. The SCLC (space charge limit current) mechanism and thermionic emission mechanism are identified for low WF and high WF electrodes. Moreover, the forming process of soft breakdown and anti-forming process of large first RESET current are observed in devices with high and low WF electrodes, respectively. The device performance is significantly improved by selecting the proper electrode. The experimental results show that the Ni/WO_{X}/W device has low operation current, large resistance window and extreme thermal stability, suitable for nonvolatile memory applications. In addition to nickel (Ni), other embodiments are directed to electrodes including at least one of: Yb, Tb, Y, La, Sc, Hf, Zr, Al, Ta, Ti, Nb, Cr, V, Zn, W, Mo, Cu, Re, Ru, Co, Rh, Pd, Pt.

Resistance-based memory has attracted much attention because of its small cell size, simple structure, high speed, and potential for 3D stacking, as discussed in Z. Wei, et al., IEDM., pp. 293-296, 12.2, 2008; and W. C. Chien, et al., SSDM., pp. 1206-1207, G-7-3, 2009; both incorporated by reference. However, the conduction mechanism is unclear for many metal oxide ReRAMs. WO_{X} ReRAM has been reported for its good electrical properties and simple process as discussed in W. C. Chien, et al., SSDM., pp. 1206-1207, G-7-3, 2009; C. H Ho, et al., Symp. VLSI Tech., pp. 228-229, 2007; W. C. Chien, et al., IMW., pp. 15-16, 2B-1, 2009; all incorporated by reference. The electrode material impacts the characteristics of WO_{X} ReRAM. The conduction mechanism strongly depends on the WF of electrodes. In addition, WF also affects significantly the forming process. In one embodiment a ReRAM uses a Ni electrode. The Ni/WO_{X}/W. ReRAM not only reduces the anti-forming current by 10× and the switching current by 3×; but also provides a larger resistance window. Furthermore, the thermal stability is highly improved to 300 years at 85° C. with at least 1 order of resistance window.

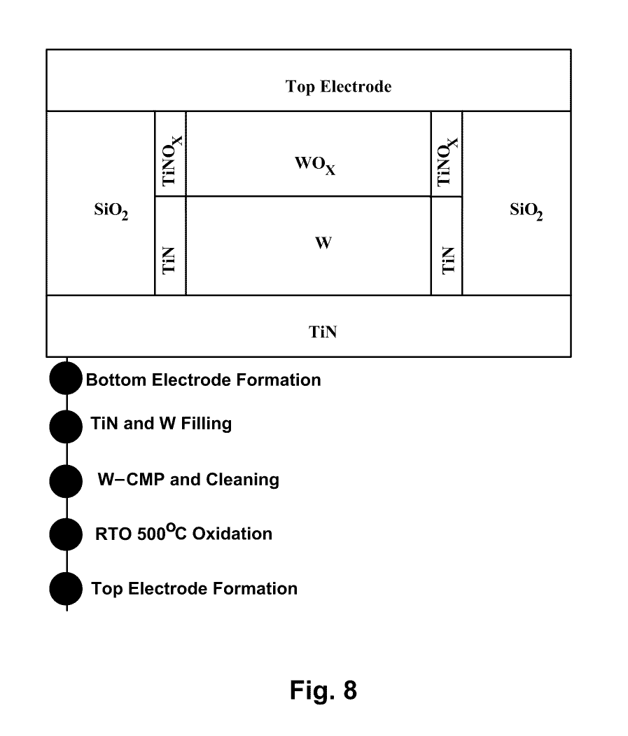

FIG. 8 shows the structure and the device fabrication process flow of the ReRAM cell. An exemplary WO_{X} cell is shown. The contact size is 0.18 μm and a 500° C. RTO (Rapid thermal oxidation) process is used for forming the WO_{N}, as discussed in W. C. Chien, et al., SSDM., pp. 1206-1207, G-7-3, 2009, incorporated by reference. Different top electrodes (TEs) are formed by PVD deposition.

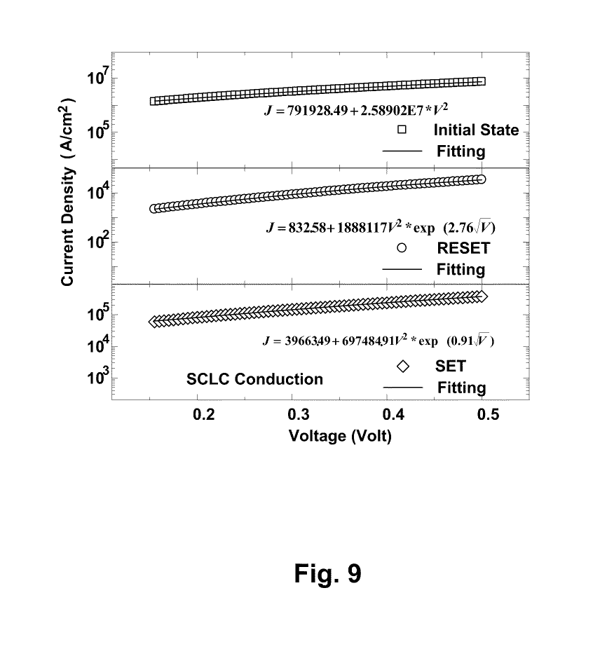

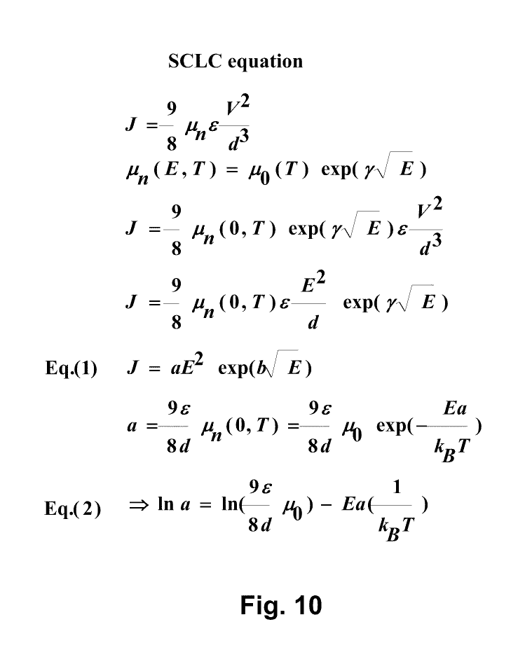

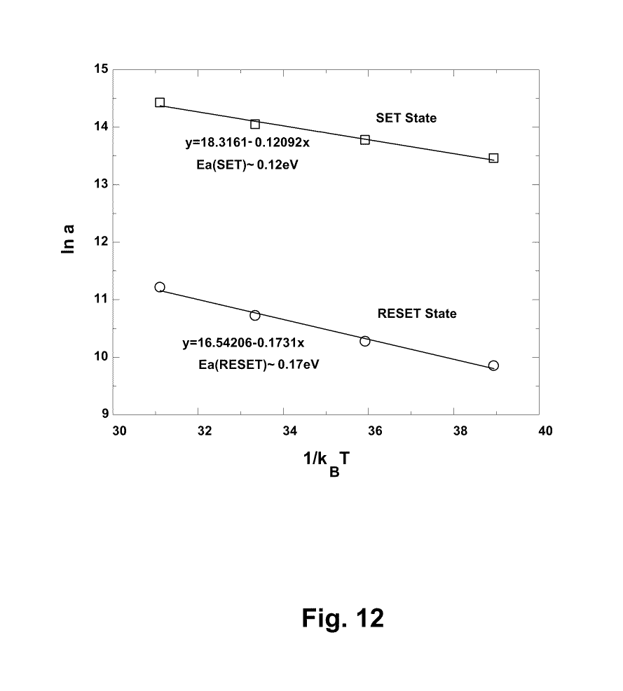

The conduction mechanism of various top electrode WO_{X} ReRAMs is studied. For a low WF TE, TiN, the IV curves of the initial, RESET and SET states all follow the SCLC mechanism, as in FIG. 9. Temperature dependence at 25° C., 50° C., 75° C., and 100° C., also confirms that the IV curves in FIG. 11 are well described by Eq. (1) of the SCLC in FIG. 10. Using Eq. (2) in FIG. 10, the activation energy Ea of conduction behavior of RESET and SET states of 0.17 eV and 0.12 eV, respectively, are obtained, as shown in FIG. 12. The RESET state shows a stronger temperature dependence corresponding to previous results, W. C. Chien, et al., IMW., pp. 15-16, 2B-1, 2009, incorporated by reference.

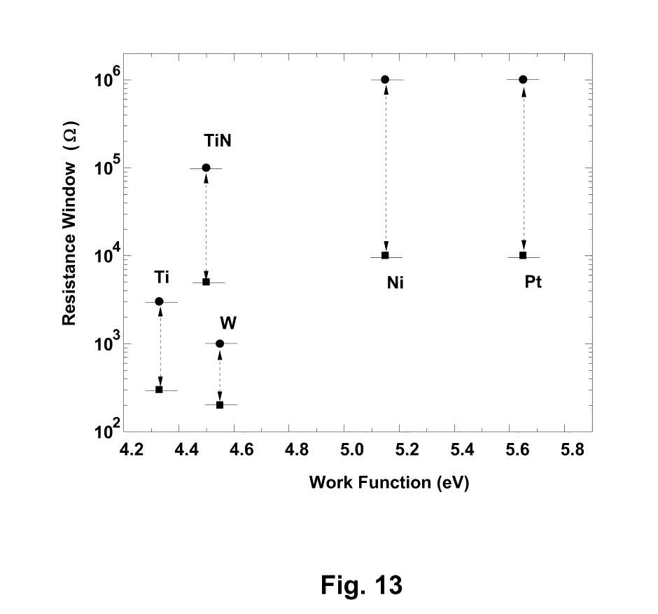

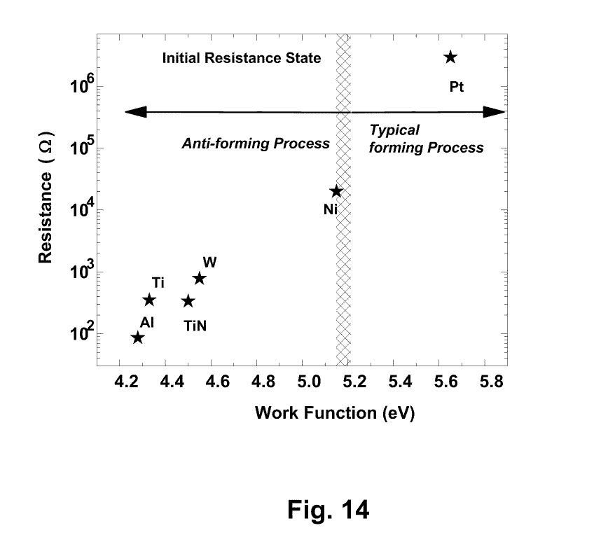

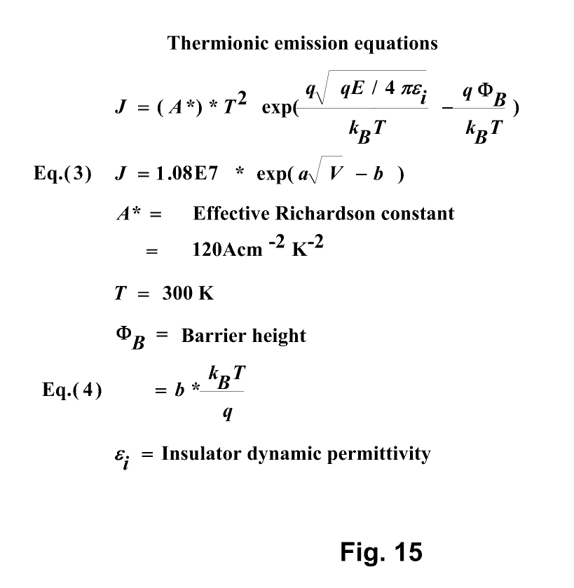

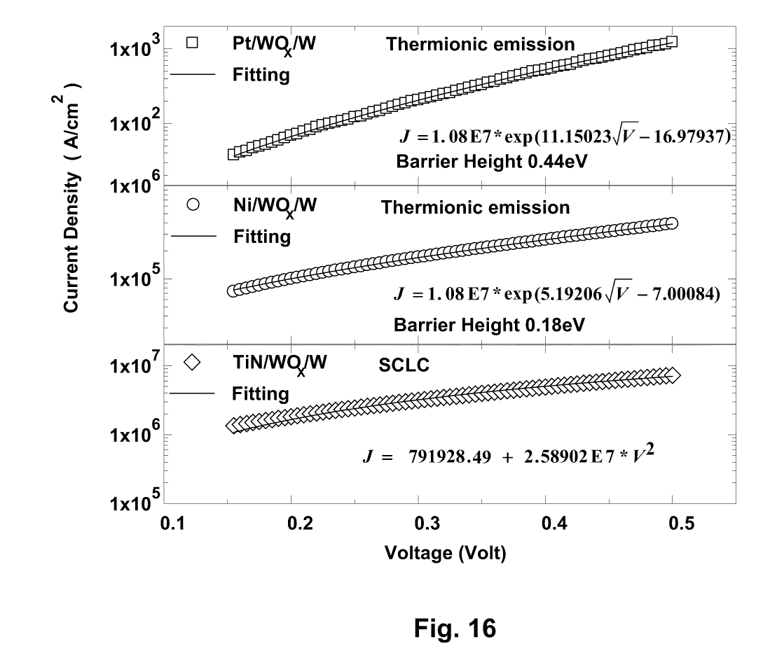

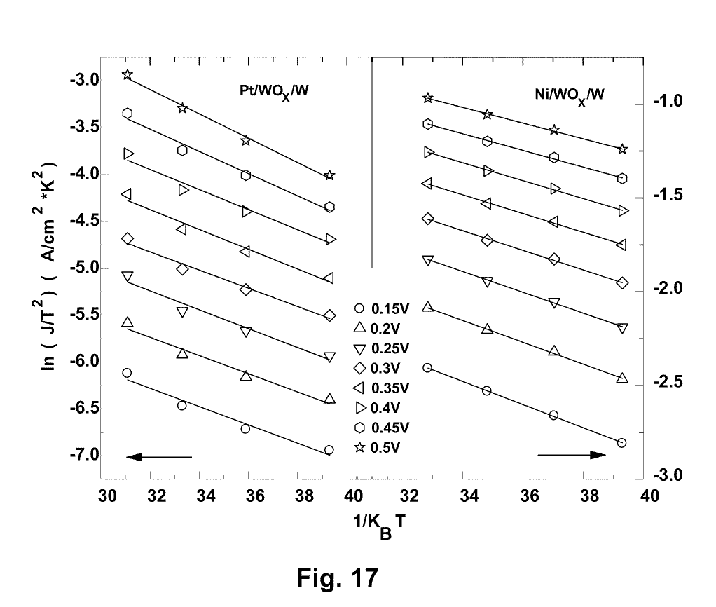

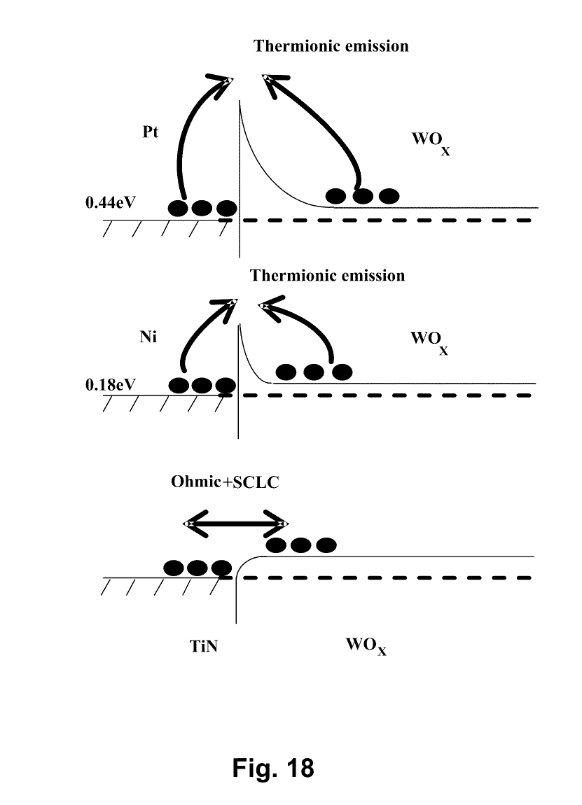

FIG. 13 shows the resistance window as a function of the WF of the TE. The devices with Pt and/or Ni TEs show higher RESET resistance and good resistance windows larger than 2 orders of magnitude, indicating that TE plays an important role for electrical properties. FIG. 14 shows the initial resistance is a function of the WF of TE, with initial state resistance increasing as the WF of TE increases. With a high WF Pt TE, a forming process is required. In contrast, for a low WF TE, an anti-forming process is required, as discussed in W. C. Chien, et al., SSDM., pp. 1206-1207, G-7-3, 2009, incorporated by reference. FIG. 16 shows the initial state IV curves for cells with Pt, Ni, and TiN TEs. Both Pt and Ni devices are well matched with thermionic emission in Eq. (3) of FIG. 15. However, TiN devices are well matched with SCLC. FIG. 17 further supports the thermionic emission mechanism for Pt/WO_{X}/W and Ni/WO_{X}/W cells. A plot of ln(J/T²) versus 1/k_{B}T yields straight lines with different electrical fields under biases of 0.15V, 0.2V, 0.25V, 0.3V, 0.35V, 0.4V, 0.45V, and 0.5V, as discussed in S. M. Sze, Physics of Semiconductor Devices, John Willey & Sons/Central Book Company, 2^{nd} edition, P. 403, 1985, incorporated by reference. The barrier heights of Pt device, 0.44 eV and Ni device, 0.18 eV are calculated by Eq. (4) of FIG. 15. The barrier heights are a function of the difference in work functions between the electrode material and the metal-oxide memory material, when the electrode work function exceeds the metal-oxide memory material work function. The schematics of conduction mechanism of WO_{X} ReRAM with Pt, Ni, and TiN are shown in FIG. 18. From the experiments discussed above, a high WF electrode such as Ni and Pt results in a large resistance window. One embodiment is a Pt electrode, although this can be difficult to process and expensive. The Ni/WO_{X}/W ReRAM is another embodiment, with further data below.

A high work function electrode material as used herein means a material in which the work function establishes a barrier as illustrated in FIG. 18 relative to the work function in the memory element, so that the conduction mechanism exhibits behavior characteristic of thermionic emission.

Device characteristics are discussed below.

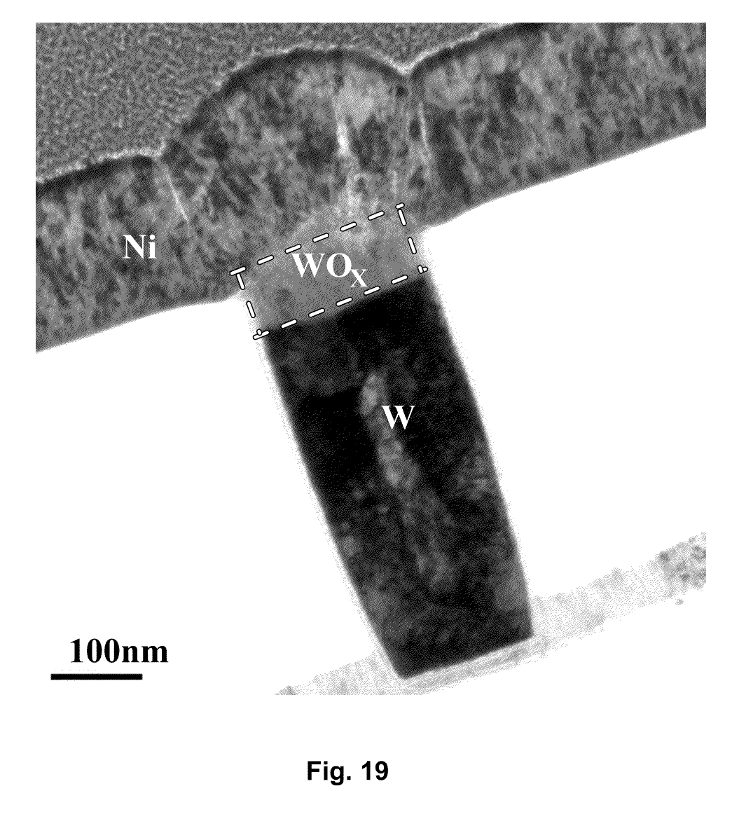

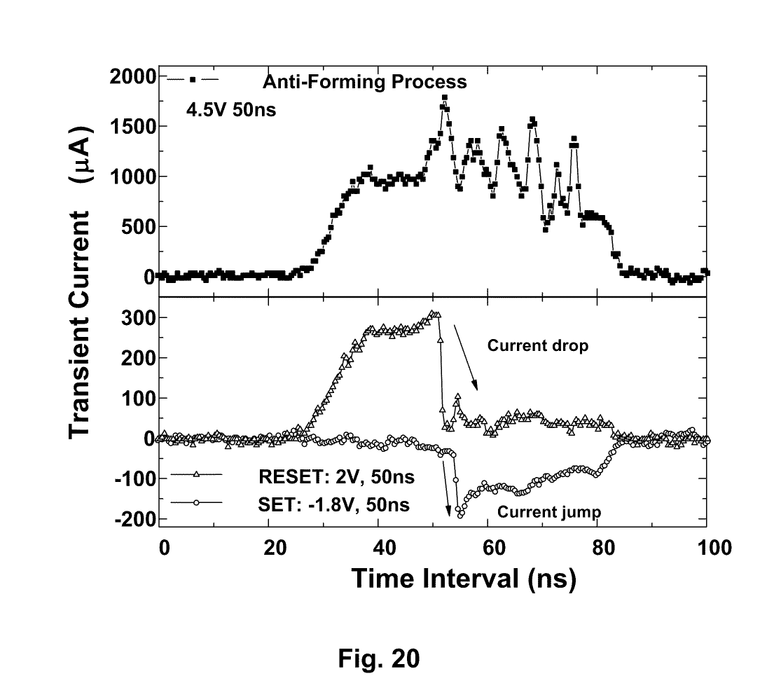

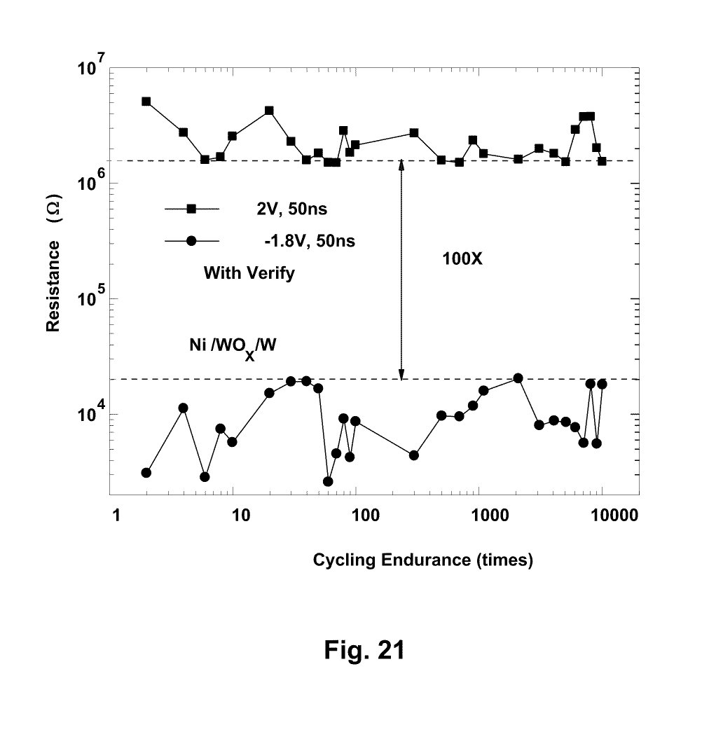

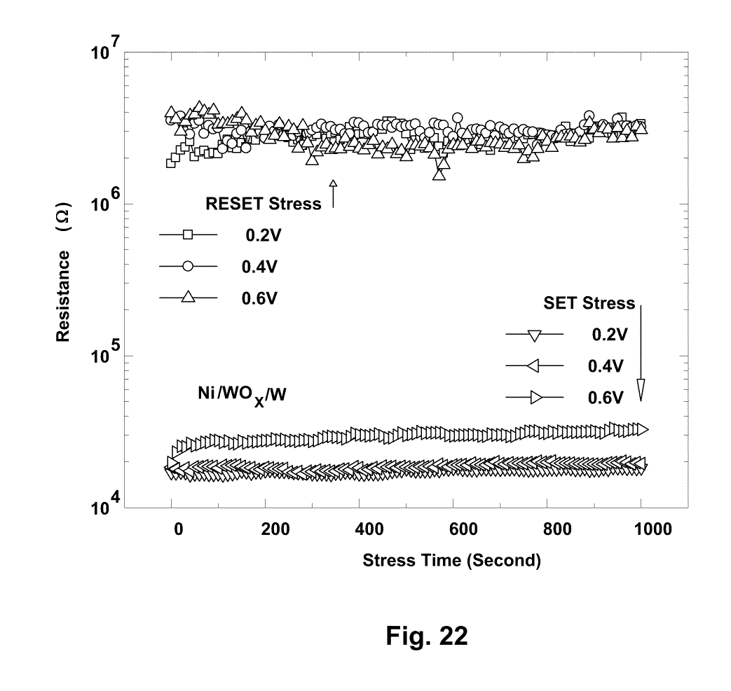

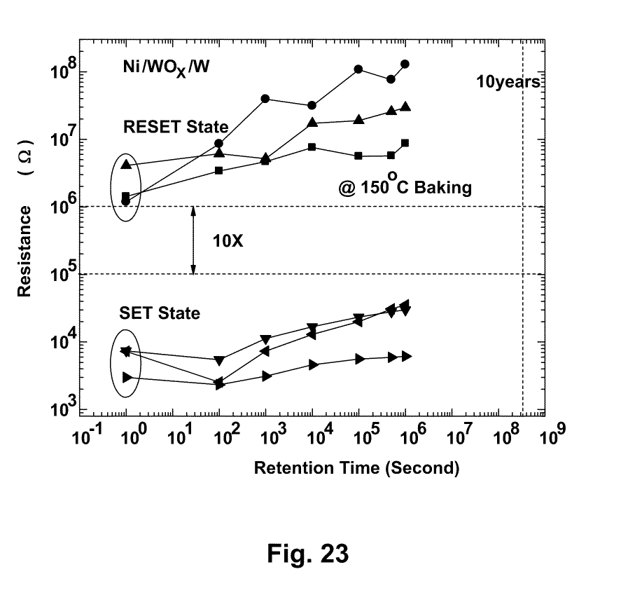

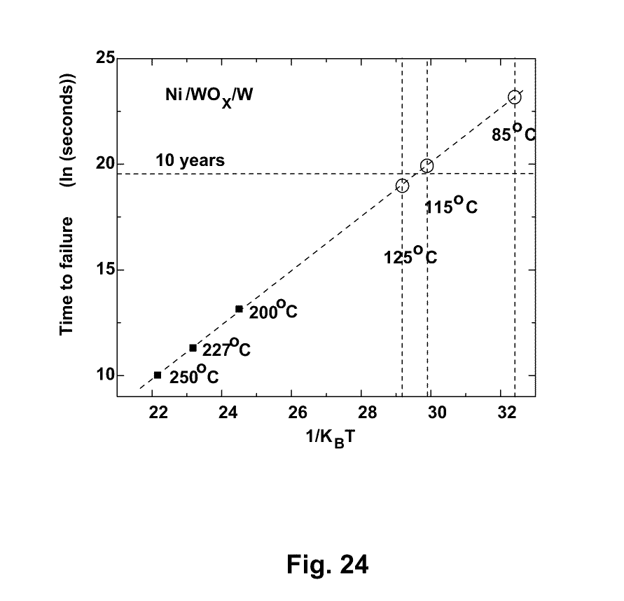

FIG. 19 shows the cross-sectional TEM of the Ni(200 nm)/WO_{X}(70 nm)/W cell. The I-t curve of the anti-forming process, and transient I-t curves for RESET and SET processes are shown in FIG. 20 for the Ni/WO_{X}/W cell. The anti-forming current is about 2 mA. After anti-forming process, the RESET (2V/50 ns) current is about 300 uA, and SET (−1.8V/50 ns) current is about 200 uA. FIG. 21 demonstrates the cycling endurance for 10 k times. To obtain tight resistance distribution, a program-verify algorithm is used, as discussed in W. C. Chien, et al., SSDM., pp. 1206-1207, G-7-3, 2009, incorporated by reference. The RESET/SET resistance window is well separated at about 1 megohm/20 kilohms, nearly 2 orders of magnitude, for over 10 k cycles. Both the SET and RESET states show good immunity to read disturb without observable degradation after up to 0.6V stressing for 1,000 seconds, as shown in FIG. 22. The retention results after baking at 150° C. are shown in FIG. 23. Both RESET and SET are well separated with at least a 10× resistance window, after two weeks of baking (10̂6 seconds), and the devices continue to function normally after baking Further retention studies are shown in FIG. 24. An activation energy Ea of 1.34 eV is deduced from the Arrhenius plot, and retention time extrapolated predicts >10 years at 115° C. and >300 years at 85° C. The failure criteria is <100 kilohms for SET.

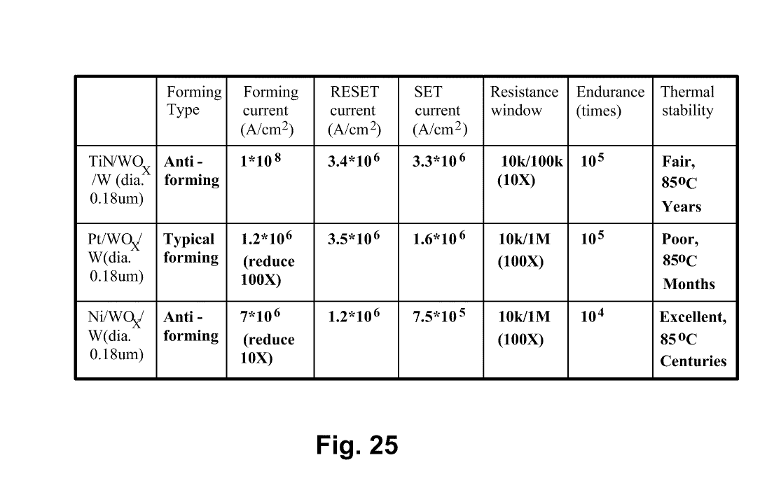

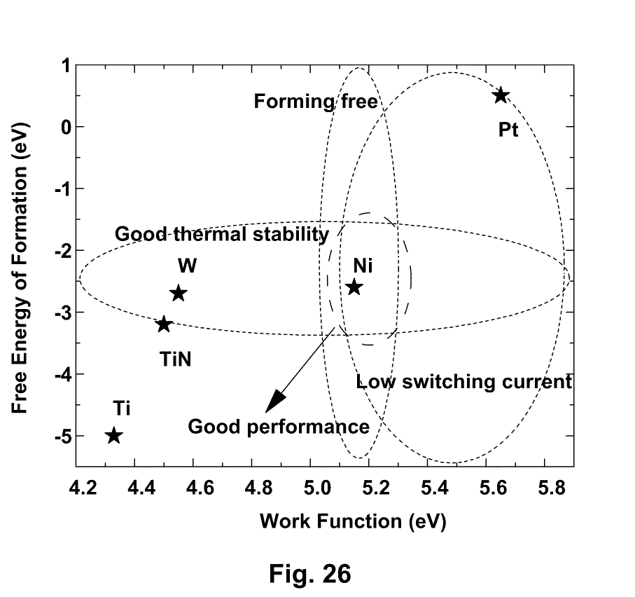

A comparison of different electrodes is shown in FIG. 25. Both Ni and Pt TEs reduce the operation current from the TiN/WO_{X}/W device. The Ni/WO_{X}/W cell shows excellent thermal stability with large resistance window and low operation current. The reason for good thermal stability may be due to that the free energies of formation of W (−2.7 eV) and Ni (−2.6 eV) oxides are similar (as discussed in Z. Wei, et al., IEDM., pp. 293-296, 12.2, 2008 and O. Sharia, et al., Phys. Rev. B., vol. 79, p. 125305, 2009; both incorporated by reference) therefore there is no driving force for degradation. FIG. 26 graphs free energies of formation versus work function.

In summary, the WF of TE plays an important role for WO_{X} ReRAM. The high WF Ni/WO_{X}/W structure shows low operation current, large resistance window, suitable endurance, good read disturbance, and excellent thermal stability.

Also, Ni/WO_{X}/W shows the good thermal stability may due to that the free energies of formation of W (−2.7 eV) and Ni (−2.6 eV) oxides are similar.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims.

What is claimed is:

1. A memory device comprising:
a metal-oxide memory element arranged in electrical series along a current path between at least a first electrode, a metal-oxide memory element adjacent to the first electrode, and a second electrode, wherein the first electrode comprises an electrode material having a first work function, the metal-oxide memory element comprises a metal-oxide material having a second work function, and the first work function is greater than the second work function.

2. The memory device of claim 1, wherein the first electrode is a top electrode and the second electrode is a bottom electrode.

3. The memory device of claim 1, wherein current through the current path is characterized by thermionic emission.

4. The memory device of claim 1, wherein the electrode material includes at least one of the following metals: Yb, Tb, Y, La, Sc, Hf, Zr, Al, Ta, Ti, Nb, Cr, V, Zn, W, Mo, Cu, Re, Ru, Co, Ni, Rh, Pd, Pt.

5. The memory device of claim 1, wherein the current path further includes, between the metal-oxide memory element and the second electrode, at least a metal element.

6. The memory device of claim 1, wherein the memory device has a resistance window of at least about a factor of 100.

7. The memory device of claim 1, wherein the electrode material comprises a metal having a first free energy of formation of an oxide that is similar to a second free energy of formation of the metal-oxide material in the metal-oxide memory element.

8. The memory device of claim 1, wherein the electrode material comprises a metal having a first free energy of formation of an oxide that is within about 0.1 eV of a second free energy of formation of the metal-oxide material in the metal-oxide memory element.

9. The memory device of claim 1, wherein the memory device has a reset current of no more than about 300 microamperes and a set current of no more than about 200 microamperes.

10. The memory device of claim 1, wherein the memory device has a reset current density of no more than about 1.2 mega-amperes per square centimeter and a set current density of no more than about 0.75 mega-amperes per square centimeter.

11. A memory device comprising:
a plurality of word lines;
a plurality of bit lines;
a plurality of memory cells accessed by the plurality of word lines and plurality of bit lines, memory cells in the plurality of memory cells including:
a metal-oxide memory element arranged in electrical series along a current path between at least a word line of the plurality of word lines and a bit line of the plurality of bit lines, wherein the metal-oxide memory element is adjacent to a first electrode comprising an electrode material having a first work function, the metal-oxide memory element comprising a metal-oxide material having a second work function, and the first work function is greater than the second work function.

12. The memory device of claim 11, wherein the first electrode is a top electrode and the second electrode is a bottom electrode.

13. The memory device of claim 11, wherein current through the current path is characterized by thermionic emission.

14. The memory device of claim 11, wherein the electrode material includes at least one of the following metals: Yb, Tb, Y, La, Sc, Hf, Zr, Al, Ta, Ti, Nb, Cr, V, Zn, W, Mo, Cu, Re, Ru, Co, Ni, Rh, Pd, Pt.

15. The memory device of claim 11, wherein the current path further includes, between the metal-oxide memory element and the second electrode, at least a metal element.

16. The memory device of claim 11, wherein memory cells in the plurality of memory cells have a resistance window of at least about a factor of 100.

17. The memory device of claim 11, wherein the electrode material comprises a metal having a first free energy of formation of an oxide that is similar to a second free energy of formation of the metal-oxide material in the metal-oxide memory element.

18. The memory device of claim 11, wherein the electrode material comprises a metal having a first free energy of formation of an oxide that is within about 0.1 eV of a second free energy of formation of the metal-oxide material in the metal-oxide memory element.

19. The memory device of claim 11, wherein memory cells in the plurality of memory cells have a reset current of no more than about 300 microamperes and a set current of no more than about 200 microamperes.

20. The memory device of claim 11, wherein memory cells in the plurality of memory cells have a reset current density of no more than about 1.2 mega-amperes per square centimeter and a set current density of no more than about 0.75 mega-amperes per square centimeter.

21. A manufacturing method, comprising:
providing a metal-oxide memory element arranged in electrical series along a current path between at least a first electrode, a metal-oxide memory element adjacent to the first electrode, and a second electrode, wherein the first electrode comprises an electrode material having a first work function, the metal-oxide memory element comprises a metal-oxide material having a second work function, and the first work function is greater than the second work function.
